(19) United States
(12) Patent Application Publication
(10) Pub. No.: US 2026/0293420 A1
(43) Pub. Date: Sep. 24, 2026

(54) LIGHT-EMITTING SUBSTRATE, MANUFACTURING METHOD THEREFOR, AND DISPLAY APPARATUS

(71) Applicants: Beijing BOE Technology Development Co., Ltd., Beijing (CN); BOE Technology Group Co., Ltd., Beijing (CN)

(72) Inventors: Zhuo LI, Beijing (CN); Yichi ZHANG, Beijing (CN)

(21) Appl. No.: 19/478,055

(22) PCT Filed: Sep. 27, 2023
(86) PCT No.: PCT/CN2023/122157

§ 371 Date: Oct. 23, 2025

(51) Int. Cl. H10K 50/115; H10K 50/15; H10K 50/16; H10K 50/17; H10K 50/814; H10K 50/824; H10K 59/122; H10K 71/10; H10K 71/60; H10K 102/00

(52) U.S. Cl. CPC H10K 50/115; H10K 50/814; H10K 50/824; H10K 59/122; H10K 71/10; H10K 71/60; H10K 50/15; H10K 50/16; H10K 50/17; H10K 2102/351

(57) ABSTRACT

A light-emitting substrate, a manufacturing method therefor, and a display apparatus. The light-emitting substrate comprises a base substrate and a light-emitting device located on the base substrate. The light-emitting device comprises: a light-emitting layer, located on the base substrate, the light-emitting layer comprising a bottom surface facing the side of the base substrate, a top surface facing away from the side of the base substrate, and a first side surface, a second side surface, a third side surface and a fourth side surface which connect the bottom surface and the top surface, the first side surface and the second side surface being oppositely arranged, and the third side surface and the fourth side surface being oppositely arranged.

### CROSS-REFERENCES TO RELATED APPLICATIONS

The present disclosure is a National Stage of International Application No. PCT/CN2023/122157, filed on Sep. 27, 2023, the entire contents of which are incorporated herein by reference.

### TECHNICAL FIELD

The present disclosure relates to the field of display technologies, and in particular to a light-emitting substrate and a manufacturing method therefor, and a display device.

### BACKGROUND

For a quantum dot light-emitting diode display (QLED) and an organic light-emitting diode (OLED) display, important characteristics such as external quantum efficiency (EQE), brightness, and service life are related to injection conditions of carriers, and in theory, the properties of each aspect of the device can reach the optimal level when the injection balance of carriers is realized. However, existing QLED and OLED displays are difficult to truly realize the injection balance of carriers, and once the device is prepared and completed, it is difficult to actively adjust the space and route.

### SUMMARY

Embodiments of the present disclosure provide a light-emitting substrate and a manufacturing method therefor, and a display device.

An embodiment of the present disclosure provides a light-emitting substrate, including a base substrate and a light-emitting device on the base substrate, where the light-emitting device includes: a light-emitting layer on the base substrate; where the light-emitting layer includes a bottom surface facing a side of the base substrate, a top surface facing away from the side of the base substrate, and a first side surface, a second side surface, a third side surface, and a fourth side surface connecting the bottom surface with the top surface; where the first side surface and the second side surface are opposite to each other, and the third side surface and the fourth side surface are opposite to each other; a first electrode group, including a first electrode and a second electrode; where the first electrode is on the base substrate and on a side of the first side surface facing away from the light-emitting layer, and the second electrode is on the base substrate and on a side of the second side surface facing away from the light-emitting layer; and a second electrode group, including a third electrode and a fourth electrode; where the third electrode is on the base substrate and on a side of the third side surface facing away from the light-emitting layer, and the fourth electrode is on the base substrate and on a side of the fourth side surface facing away from the light-emitting layer; where the first electrode, the second electrode, the third electrode, and the fourth electrode are independent from each other.

In a possible implementation, in the light-emitting substrate provided by an embodiment of the present disclosure, the light-emitting device further includes: a first carrier layer between at least one electrode in the first electrode group and the light-emitting layer; and a second carrier layer between at least one electrode in the second electrode group and the light-emitting layer.

In a possible implementation, in the light-emitting substrate provided by an embodiment of the present disclosure, the first carrier layer is disposed between the first electrode and the light-emitting layer and between the second electrode and the light-emitting layer; and the second carrier layer is disposed between the third electrode and the light-emitting layer and between the fourth electrode and the light-emitting layer.

In a possible implementation, in the light-emitting substrate provided by an embodiment of the present disclosure, the first carrier layer includes at least one of an electron transport layer and an electron injection layer; and the second carrier layer includes at least one of a hole transport layer and a hole injection layer; where a first carrier injected into the first carrier layer is an electron, and a second carrier injected into the second carrier layer is a hole; where based on that the first carrier layer includes the electron transport layer and the electron injection layer, the electron transport layer is between the electron injection layer and the light-emitting layer; and based on that the second carrier layer includes the hole transport layer and the hole injection layer, the hole transport layer is between the hole injection layer and the light-emitting layer.

In a possible implementation, the light-emitting substrate provided by an embodiment of the present disclosure further includes a pixel defining layer on the base substrate; where the pixel defining layer is provided with a pixel opening, and the light-emitting device is in the pixel opening; where a shape of an orthographic projection of the pixel opening on the base substrate is square.

In a possible implementation, in the light-emitting substrate provided by an embodiment of the present disclosure, the first carrier layer and the second carrier layer are independent from each other, or the first carrier layer and the second carrier layer are in contact with each other.

In a possible implementation, the light-emitting substrate provided by an embodiment of the present disclosure further includes a pixel defining layer on the base substrate; where the pixel defining layer is provided with a pixel opening, and the light-emitting device is in the pixel opening; where the pixel opening includes: a square opening, and a first opening, a second opening, a third opening, and a fourth opening respectively connected to side edges of the square opening and extending from sides of the square opening to outside; and a shape of an orthographic projection of the square opening on the base substrate is square; and openings, that are adjacent to each other, of the first opening, the second opening, the third opening, and the fourth opening are spaced apart from each other, and the square opening communicates with the first opening, the second opening, the third opening, and the fourth opening.

In a possible implementation, in the light-emitting substrate provided by an embodiment of the present disclosure, the first electrode is in the first opening, the second electrode is in the second opening, the third electrode is in the third opening, and the fourth electrode is in the fourth opening; the first carrier layer is in the first opening and/or the second opening, and the second carrier layer is in the third opening and/or the fourth opening; and the light-emitting layer at least covers the square opening and is in contact with the first carrier layer and the second carrier layer.

In a possible implementation, the light-emitting substrate provided by an embodiment of the present disclosure further includes: a planarization layer on a side of the base substrate facing the light-emitting layer, a driving circuit layer between the planarization layer and the base substrate, and an encapsulation layer on a side of the light-emitting layer facing away from the base substrate; where the driving circuit layer includes: a first driving circuit corresponding one-to-one with the first electrode group, and a second driving circuit corresponding one-to-one with the second electrode group; where the first electrode is electrically connected to the first driving circuit through a first via hole penetrating through the planarization layer, the second electrode is electrically connected to the first driving circuit through a second via hole penetrating through the planarization layer, the third electrode is electrically connected to the second driving circuit through a third via hole penetrating through the planarization layer, and the fourth electrode is electrically connected to the second driving circuit through a fourth via hole penetrating through the planarization layer.

In a possible implementation, the light-emitting substrate provided by an embodiment of the present disclosure further includes a metal reflective layer between the planarization layer and the light-emitting layer; where an orthographic projection of the metal reflective layer on the base substrate does not overlap with an orthographic projection of the first electrode group and the second electrode group on the base substrate.

In a possible implementation, the light-emitting substrate provided by an embodiment of the present disclosure further includes a metal reflective layer between the encapsulation layer and the light-emitting layer; where an orthographic projection of the metal reflective layer on the base substrate does not overlap with an orthographic projection of the first electrode group and the second electrode group on the base substrate.

In a possible implementation, in the light-emitting substrate provided by an embodiment of the present disclosure, along a direction pointing from the first electrode to the second electrode, a thickness of the light-emitting layer ranges from 20 nm to 750 nm; and along a direction pointing from the third electrode to the fourth electrode, a thickness of the light-emitting layer ranges from 20 nm to 750 nm.

In a possible implementation, in the light-emitting substrate provided by an embodiment of the present disclosure, along a direction pointing from the first electrode to the second electrode, a thickness of the electron injection layer ranges from 20 nm to 250 nm and a thickness of the electron transport layer ranges from 20 nm to 250 nm; and along a direction pointing from the third electrode to the fourth electrode, a thickness of the hole injection layer ranges from 5 nm to 150 nm and a thickness of the hole transport layer ranges from 5 nm to 200 nm.

In a possible implementation, along a direction pointing from the first electrode to the second electrode, a thickness of the first electrode ranges from 50 nm to 400 nm and a thickness of the second electrode ranges from 50 nm to 400 nm; and along a direction pointing from the third electrode to the fourth electrode, a thickness of the third electrode ranges from 50 nm to 400 nm and a thickness of the fourth electrode ranges from 50 nm to 400 nm.

In a possible implementation, in the light-emitting substrate provided by an embodiment of the present disclosure, along a direction perpendicular to a plane where the base substrate is located, a height of the pixel defining layer ranges from 150 nm to 2000 nm, and a height of the light-emitting layer is 10 nm-500 nm; a height of the first electrode group is greater than or equal to 100 nm and less than or equal to a sum of a height of the pixel defining layer and 40 nm, and a height of the second electrode group is greater than or equal to 100 nm and less than or equal to the sum of the height of the pixel defining layer and 40 nm; and a height of the first carrier layer is greater than or equal to 50 nm and less than or equal to a sum of a first height and 20 nm, and a height of the second carrier layer is greater than or equal to 50 nm and less than or equal to the sum of the first height and 20 nm; where the first height is a smaller height of the height of the first electrode group and the height of the second electrode group.

Correspondingly, an embodiment of the present disclosure further provides a display device, including the light-emitting substrate according to any one of the above embodiments of the present disclosure.

Correspondingly, an embodiment of the present disclosure further provides a manufacturing method for a light-emitting substrate, including: providing a base substrate; forming a first electrode group on the base substrate; where the first electrode group includes a first electrode and a second electrode opposite to each other; forming a second electrode group on the base substrate; where the second electrode group includes a third electrode and a fourth electrode opposite to each other; where the first electrode, the second electrode, the third electrode, and the fourth electrode enclose an annular structure, and the first electrode, the second electrode, the third electrode, and the fourth electrode are independent from each other; and forming a light-emitting layer in the annular structure on the base substrate; where the light-emitting layer includes a bottom surface facing a side of the base substrate, a top surface facing away from the side of the base substrate, and a first side surface, a second side surface, a third side surface, and a fourth side surface connecting the bottom surface with the top surface; where the first side surface and the second side surface are opposite to each other, the third side surface and the fourth side surface are opposite to each other, the first electrode is on a side of the first side surface facing away from the light-emitting layer, the second electrode is on a side of the second side surface facing away from the light-emitting layer, the third electrode is on a side of the third side surface facing away from the light-emitting layer, and the fourth electrode is on a side of the fourth side surface facing away from the light-emitting layer.

In a possible implementation, in the above manufacturing method provided by the embodiments of the present disclosure, before forming the light-emitting layer, the method further includes: forming a first carrier layer between the first electrode and the light-emitting layer and/or between the second electrode and the light-emitting layer; and forming a second carrier layer between the third electrode and the light-emitting layer and/or between the fourth electrode and the light-emitting layer.

### BRIEF DESCRIPTION OF FIGURES

FIG. 1 is a schematic structural diagram of a light-emitting device provided in the related art.

FIG. 2 is a schematic structural diagram of a light-emitting device according to embodiments of the present disclosure.

FIG. 3A is another schematic structural diagram of a light-emitting device according to embodiments of the present disclosure.

FIG. 3B is a shape of a pixel opening in FIG. 3A.

FIG. 4 is a J-V (current-voltage) test performed on a contact setting and a non-contact setting between a first carrier layer and a second carrier layer according to the present disclosure.

FIG. 5 is a schematic diagram of a flow direction of electrons and a flow direction of holes in a light-emitting device provided by the present disclosure.

FIG. 6 is a schematic cross-sectional view along a direction CC′ in FIG. 2 and FIG. 3A.

FIG. 7 is a schematic cross-sectional view along a direction CC′ in FIG. 2 and FIG. 3A.

FIG. 8 is a schematic cross-sectional view along a direction DD′ in FIG. 2 and FIG. 3A.

FIG. 9 is a schematic cross-sectional view along a direction DD′ in FIG. 2 and FIG. 3A.

FIG. 10 is a schematic diagram of a thickness and an energy level value of each film layer in a hole-only device (HOD) along a direction pointing from a third electrode to a fourth electrode direction.

FIG. 11 is a schematic diagram of a change in current density J of a HOD corresponding to quantum dot (QD) light-emitting layers of different thicknesses.

FIG. 12 is a schematic diagram of a change in current density J of a HOD corresponding to different voltages.

FIG. 13 is a schematic diagram of a thickness and an energy level value of each film layer in an electron-only device (EOD) along a direction pointing from a first electrode to a second electrode.

FIG. 14 is a schematic diagram of a change in current density J of an EOD corresponding to QD light-emitting layers of different thicknesses.

FIG. 15 is a schematic diagram of a change in current density J of an EOD corresponding to different voltages.

FIG. 16 is a schematic flowchart of a manufacturing method for a light-emitting substrate according to embodiments of the present disclosure.

FIG. 17 is another schematic flowchart of a manufacturing method for a light-emitting substrate according to embodiments of the present disclosure.

FIGS. 18A to 18O are schematic structural diagrams after each step is performed when manufacturing the light-emitting device shown in FIG. 2 according to embodiments of the present disclosure.

FIGS. 19A to 19O are schematic structural diagrams after each step is performed when manufacturing the light-emitting device shown in FIG. 3A according to embodiments of the present disclosure.

FIG. 20 is a schematic structural diagram of a display device according to embodiments of the present disclosure.

### DETAILED DESCRIPTION

In order to make the objectives, technical solutions, and advantages of the embodiments of the present disclosure clearer, the technical solutions of the embodiments of the present disclosure will be clearly and completely described below with reference to the accompanying drawings of the embodiments of the present disclosure. Apparently, the described embodiments are some rather than all of the embodiments of the present disclosure. Moreover, in the case of no conflict, the embodiments in the present disclosure and the features in the embodiments may be combined with each other. Based on the described embodiments of the present disclosure, all other embodiments obtained by those of ordinary skill in the art without creative efforts shall fall within the claimed scope of the present disclosure.

Unless otherwise defined, technical or scientific terms used in the present disclosure shall have the ordinary meaning as understood by one of ordinary skill in the art to which the present disclosure belongs. The words “include” or “comprise” used in the present disclosure mean that the elements or objects preceding the word cover the elements or objects listed after the word and their equivalents, but do not exclude other elements or objects. Words such as “connect” or “couple” are not limited to physical or mechanical connections, but may include electrical connections, whether direct or indirect. The terms “inner”, “outer”, “upper”, “lower” and the like are only used to represent relative positional relationships, and when the absolute position of the described object changes, the relative positional relationship may also change accordingly.

It should be noted that the sizes and shapes of the patterns in the drawings do not reflect the true scale, and the purpose is only to illustrate the content of the present disclosure. The same or similar reference numerals throughout represent the same or similar elements or elements having the same or similar functions.

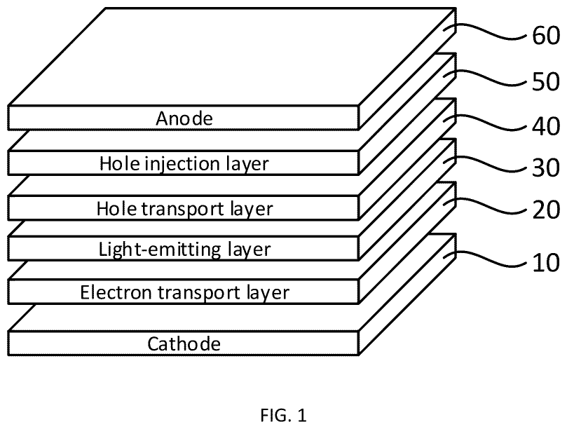

An existing self-luminous QLED or OLED device structure is based on a laminated structure, that is, the functional layers are stacked in parallel. As shown in FIG. 1, the self-luminous QLED or the OLED device structure includes a cathode 10, an electron transport layer 20, a light-emitting layer 30, a hole transport layer 40, a hole injection layer 50, an anode 60, and the like stacked in sequence, and the functional layers are stacked layer by layer between the cathode 10 and the anode 60 to form a laminated structure parallel to each other. The device performance, including external quantum efficiency (EQE), brightness, lifetime, and the like, is improved on the basis of the stacked device structure framework shown in FIG. 1. However, the performance of these devices is related to the injection conditions of carriers, and in theory, the performance of each aspect of the device can reach the optimal level when the injection balance of carriers is realized. The traditional laminated device mainly adjusts the carrier balance through the regulation of each functional layer material itself (e.g., the energy level, the mobility, the work function, the refractive index, the cleanliness, etc.), and the regulation of the film layer itself (the film thickness, the topography, the roughness, the interface, etc.), in order to achieve the matching between the performance parameters of the functional layers, so as to achieve the injection balance of the carriers in the light-emitting layer 30, so that the carriers are compounded into excitons, and the optimal performance of the QLED or the OLED device is achieved. However, the parameters that need to be regulated are very impurity, the material performance parameter of change and the interface between the layers have a large combination of factors, which may affect the efficiency of the injection and the device. In this way, during optimization and regulation, it is often difficult to comprehensively consider, and it is difficult to truly realize the injection balance of carriers. In addition, after the device fabrication is completed, the device property is basically determined, and there is no effective regulation means and route.

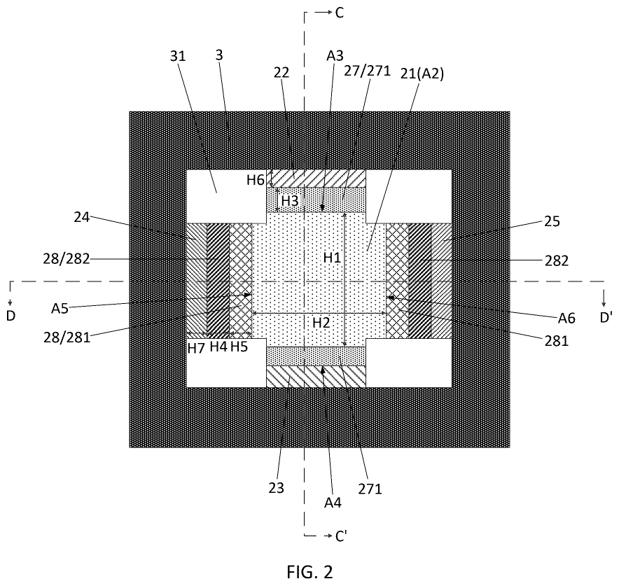

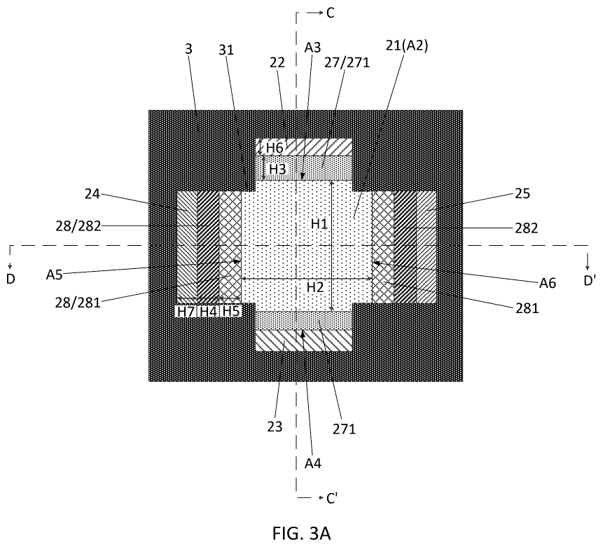

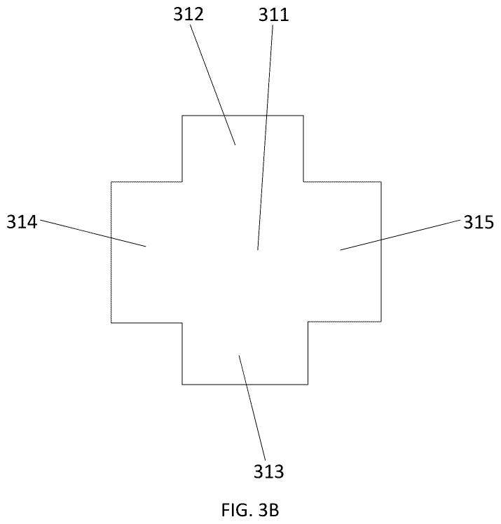

In view of this, embodiments of the present disclosure provide a light-emitting substrate, as shown in FIG. 2 and FIG. 3A, including a base substrate 1 and a light-emitting device 2 located on the base substrate 1. The light-emitting device 2 includes a light-emitting layer 21 on the base substrate 1, a first electrode group (22 and 23), and second electrode group (24 and 25).

The light-emitting layer 21 includes a bottom surface A1 facing a side of the base substrate 1, a top surface A2 facing away from the side of the base substrate 1, and a first side surface A3, a second side surface A4, a third side surface A5, and a fourth side surface A6 connecting the bottom surface A1 and the top surface A2, where the first side surface A3 and the second side surface A4 are disposed opposite to each other, and the third side surface A5 and the fourth side surface A6 are disposed opposite to each other.

The first electrode group (22 and 23) includes a first electrode 22 and a second electrode 23, where the first electrode 22 is located on the base substrate 1 and is located on a side of the first side surface A3 facing away from the light-emitting layer 21, and the second electrode 23 is located on the base substrate 1 and located on a side of the second side surface A4 facing away from the light-emitting layer 21;

The second electrode group (24 and 25) includes a third electrode 24 and a fourth electrode 25, the third electrode 24 is located on the base substrate 1 and is located on a side of the third side surface A5 facing away from the light-emitting layer 21, and the fourth electrode 25 is located on the base substrate 1 and located on a side of the fourth side surface A6 facing away from the light-emitting layer 21. The first electrode 22, the second electrode 23, the third electrode 24, and the fourth electrode 25 are independent from each other.

According to the light-emitting substrate provided by the embodiments of the present disclosure, the functional layers of the light-emitting device are disposed on the same plane, that is, the shape of the light-emitting device may be similar to that of the vertical orthogonal-type device structure, and the holes and electrons in the light-emitting device can be regulated separately by applying bias voltages of different values on the two groups of electrodes, so that the true injection balance of holes and electrons can be more easily achieved.

Optionally, the base substrate may be a flexible substrate or a rigid substrate, and the flexible substrate may be, e.g., a PI substrate, and the rigid substrate may be, e.g., a glass substrate.

Optionally, the light-emitting layer in the light-emitting device provided by the embodiments of the present disclosure may be a quantum dot light-emitting layer, or may be an organic light-emitting layer, and certainly is not limited thereto.

Optionally, when the light-emitting layer is a quantum dot light-emitting layer, the quantum dots for manufacturing the quantum dot light-emitting layer include, but are not limited to, CdS, CdSe, ZnSe, ZnTeSe, InP, PbS, CsPbCl3, CsPbBr3, CsPbI3, CdS/ZnS, CdSe/ZnS, ZnSe, ZnSeTe, InP/ZnS, PbS/ZnS, CsPbCl3/ZnS, CsPbBr3/ZnS, CsPbI3/ZnS, CdS/ZnSeS/ZnS, CdSe/ZnSeS/ZnS, ZnSe/ZnSeS/ZnS, ZnSeTe/ZnSeS/ZnS, InP/ZnS, PbS/ZnS, CsPbCI3/ZnS, CsPbBr3/ZnS, CsPbI3/ZnS, and other quantum dots. Optionally, the shape of the quantum dot includes, but is not limited to spherical, spherical, ellipsoidal, polyhedron, rod, cross, ring, and any other geometric shapes of quantum dot materials.

During specific implementation, the principle that the electroluminescent device emits light is: the holes at the anode and the electrons at the cathode are transported to the light-emitting layer and are combined to emit light. Due to the difference between the energy level barrier between the anode with the light-emitting layer and the cathode with the light-emitting layer, the transmission of the holes and the electrons are difficult and the transmission rates and quantities of them are also different. In order to balance the concentrations of electrons and holes, in the above-mentioned light-emitting substrate provided by the embodiments of the present disclosure, as shown in FIG. 2 and FIG. 3A, the light-emitting device 2 further includes: a first carrier layer 27 located between at least one electrode (the first electrode 22 and/or the second electrode 23) of the first electrode groups (22 and 23) and the light-emitting layer 21, and a second carrier layer 28 located between at least one electrode (the third electrode 24 and/or the fourth electrode 25) and the light-emitting layer 21 of the second electrode groups (24 and 25).

In this way, the first carrier may be injected into the first carrier layer 27 through the first electrode 22 and/or the second electrode 23, and the first carrier may be an electron(s) or a hole(s).

In this way, the second carrier may be injected into the second carrier layer 28 through the third electrode 24 and/or the fourth electrode 25. When the first carrier is the electron, the second carrier is the hole; and when the first carrier is the hole, the second carrier is the electron.

During specific implementation, in order to more effectively balance the concentrations of electrons and holes injected into the light-emitting layer, in the light-emitting substrate provided by the embodiments of the present disclosure, as shown in FIG. 2 and FIG. 3A, the first carrier layer 27 is provided between the first electrode 22 and the light-emitting layer 21 and between the second electrode 23 and the light-emitting layer 21.

The second carrier layer 28 is provided between the third electrode 24 and the light-emitting layer 21 and between the fourth electrode 25 and the light-emitting layer 21. Optionally, the first carrier layer 27 includes at least one of an electron transport layer 271 and an electron injection layer (not shown), the second carrier layer 28 includes at least one of a hole transport layer 281 and a hole injection layer 282, the first carrier is the electron, and the second carrier is the hole. When the first carrier layer 27 includes the electron transport layer 271 and the electron injection layer, the electron transport layer 271 is arranged close to the light-emitting layer 21; and when the second carrier layer 28 includes the hole transport layer 281 and the hole injection layer 282, the hole transport layer 281 is arranged close to the light-emitting layer 21. In this way, the first carrier and the second carrier can reach the light-emitting layer 21 through the film layers with different thicknesses, and the injection efficiency of electrons and holes can be regulated by using the difference in the transmission paths, so that different carriers reach equilibrium. In addition, in the present disclosure, the holes and electrons in the light-emitting device are also regulated respectively by applying bias voltages of different values on the two groups of electrodes, so as to more easily realize the true injection balance of holes and electrons.

During specific implementation, in the light-emitting substrate provided by the embodiments of the present disclosure, as shown in FIG. 2 and FIG. 3A, the light-emitting device 2 has two electrode groups parallel to each other, an electron transport layer 271 and a light-emitting layer 21 are provided between the first electrode 22 and the second electrode 23, and these layers are arranged in parallel; and a hole injection layer 282, a hole transport layer 281, and a light-emitting layer 21 are provided between the third electrode 24 and the fourth electrode 25, and these layers are arranged in parallel. The structure of the light-emitting device 2 may be a vertical (or approximately vertical) orthogonal device structure, a plane where a hole injection layer 282 is located and a plane a hole transport layer 281 is located are spatially perpendicular (or approximately perpendicular) to a plane where the electron transport layer 271 is located. The first electrode 22 and the second electrode 23 are also perpendicular (or approximately perpendicular) to the third electrode 24 and the fourth electrode 25. The first electrode 22 and the second electrode 23 in one group are parallel to each other, and the third electrode 24 and the fourth electrode 25 in another group are parallel to each other, that is, the first electrode 22 is parallel to the second electrode 23, the third electrode 24 is parallel to the fourth electrode 25. In this way, the device structure formed between the first electrode 22 and the second electrode 232 is a complete electron-only device (EOD) structure, the device structure formed between the third electrode 24 and the fourth electrode 25 is a complete hole-only device (HOD) structure, and the light-emitting layer 21 between the two electrode groups is a shared light-emitting layer. Therefore, the first electrode 22 and the second electrode 23 can be driven separately to regulate the concentration of electrons, and the third electrode 24 and the fourth electrode 25 can be driven separately to achieve the regulation of the concentration of the holes, thereby achieving the actual injection balance of holes and electrons.

In specific implementation, in the light-emitting substrate provided by the embodiments of the present disclosure, as shown in FIG. 2 and FIG. 3A, the light-emitting substrate further includes a pixel defining layer 3 located on the base substrate 1, the pixel defining layer 3 has a pixel opening 31, and the light-emitting device 2 is located in the pixel opening 31.

Optionally, as shown in FIG. 2, the shape of the pixel opening 21 is square. Since the functional layers of the light-emitting device 2 are generally manufactured in the square pixel opening 21 by a photolithography process, and it is necessary to ensure that the two groups of electrodes do not contact with each other, the square pixel opening 21 is more suitable for the high exposure precision of the photolithography machine, and the matching etching accuracy is also high, so that the two electrode groups are not in contact with each other without the aid of the structure of the pixel defining layer 3, that is, the first electrode 22 is not in contact with the third electrode 24 and the fourth electrode 25 in space, and the second electrode 23 is not in contact with the third electrode 24 and the fourth electrode 25 in space.

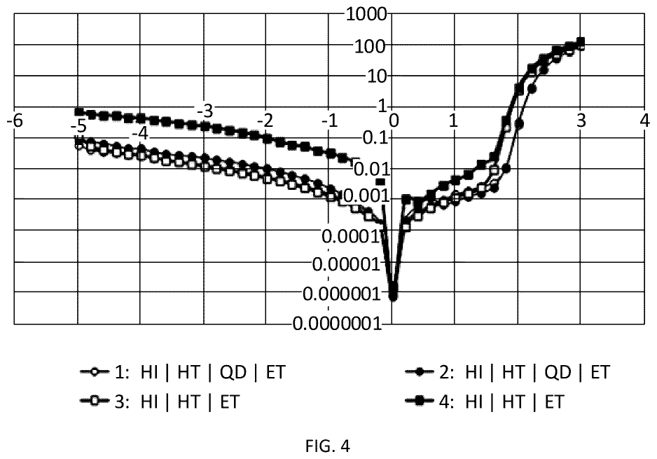

During specific implementation, in the light-emitting substrate provided by the embodiments of the present disclosure, as shown in FIG. 2, the first carrier layer 27 and the second carrier layer 28 are independent from each other. Of course, the first carrier layer 27 and the second carrier layer 28 may also be in contact with each other. The inventors of the present disclosure perform J-V (current-voltage) testing on the contact setting and non-contact setting between the first carrier layer 27 and the second carrier layer 28. As shown in FIG. 4, the curve 1 is a J-V curve corresponding to a first group of QLED devices of a structure of traditional laminated layers (structure: the anode/hole injection layer/hole transport layer/quantum dot light-emitting layer/electron transport layer/cathode, Anode|HI|HT|QD|ET|Cathode), and the curve 2 is a J-V curve corresponding to a second group of QLED devices of a structure of traditional laminated layers (structure: the anode/hole injection layer/hole transport layer/quantum dot light-emitting layer/electron transport layer/cathode, Anode|HI|HT|QD|ET|Cathode), and the curve 3 is a J-V curve corresponding to the first group of QLED devices of a structure of traditional laminated layers with the quantum dot light-emitting layer removed (structure: the anode/hole injection layer/hole transport layer/electron transport layer/cathode, Anode|HI|HT|ET|Cathode), and the curve 4 is a J-V curve corresponding to the second group of QLED devices of a structure of traditional laminated layers with the quantum dot light-emitting layer removed (structure: the anode/hole injection layer/hole transport layer/electron transport layer/cathode, Anode|HI|HT|ET|Cathode). The J-V curve experiment result shown in FIG. 4 shows that for a QLED device of the structure of traditional laminated layers (structure: the anode/hole injection layer/hole transport layer/quantum dot light-emitting layer/electron transport layer/cathode) and the device with the quantum dot light-emitting layer removed only (structure: anode/hole injection layer/hole transport layer/electron transport layer/cathode), at the same voltage, the difference between the current densities of the currents of the two is not large, that is, when the first carrier layer 27 and the second carrier layer 28 are completely in direct contact with each other, the formed diode leakage current is not large. Thus, the first carrier layer 27 and the second carrier layer 28 in the present disclosure may be in contact with each other.

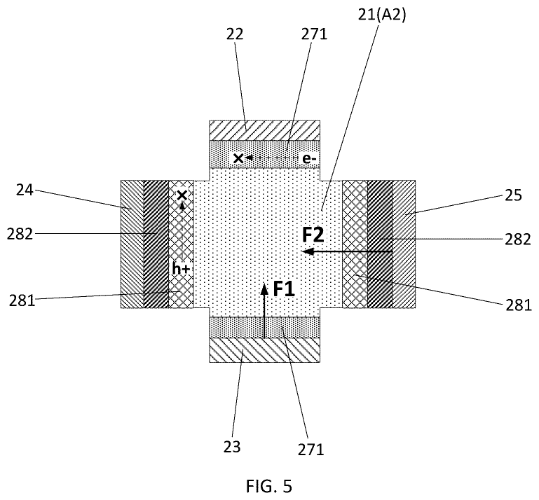

As shown in FIG. 5, FIG. 5 is a schematic diagram of the flow direction F1 of electrons and the flow direction F2 of holes in the light-emitting device. Since the first electrode group and the second electrode group are perpendicular to each other, the electric field applied by the first electrode group is perpendicular to or approximately perpendicular to the electric field applied by the second electrode group, and the electrons (e⁻) and the hole (h⁺) are respectively driven to be injected into the light-emitting layer 21, and the paths (the flow direction F1 of electrons and the flow direction F2 of holes) of them are also perpendicular or approximately perpendicular. In this case, the transverse migrations of electrons and holes in the first carrier layer 27 and the second carrier layer 28 are very small (represented by “x” in the schematic diagram). Therefore, on the basis of the J-V curve experimental result shown in FIG. 4, it is possible to further verify that the contact between the first carrier layer 27 and the second carrier layer 28 does not cause obvious leakage current of the light-emitting device, and does not significantly affect the electrical performance of the light-emitting device.

However, when the exposure accuracy requirement of the photolithography machine is relatively low, it is impossible to realize that the two groups of electrodes are not in contact with each other when the two groups of electrodes are not in contact with each other, that is, the first electrode 22 is spatially separated from the third electrode 24 and the fourth electrode 25 by means of the pixel definition layer 3, the second electrode 23 is spatially separated from the third electrode 24 and the fourth electrode 25 by means of the pixel definition layer 3. As shown in FIG. 3A and FIG. 3B, FIG. 3B is a schematic diagram of the pixel opening 31 in FIG. 3A. A shape of an orthographic projection of the pixel opening 31 on the base substrate 1 includes: a square opening 311, and a first opening 312, a second opening 313, a third opening 314, and a fourth opening 315 respectively connected to side edges of the square opening 311 and facing away from the square opening 311. Adjacent openings of the first opening 312, the second opening 313, the third opening 314, and the fourth opening 315 are arranged at intervals, and the square opening 311 communicates with the first opening 312, the second opening 313, the third opening 314, and the fourth opening 315. As such, the first electrode 22 may be disposed within the first opening 312, the second electrode 23 may be disposed within the second opening 313, the third electrode 24 may be disposed within the third opening 314, the fourth electrode 25 may be disposed within the fourth opening 25, that is, the first electrode 22, the second electrode 23, the third electrode 24, and the fourth electrode 25 are spaced apart from each other by the first opening 312, the second opening 313, the third opening 314, and the fourth opening 315. The first carrier layer 27 is arranged in the first opening 312 and/or the second opening 313, the second carrier layer 28 is arranged in the third opening 314 and/or the fourth opening 315, that is, the first carrier layer 27 and the second carrier layer 28 are spaced apart from each other by the first opening 312, the second opening 313, the third opening 314, and the fourth opening 315. Moreover, the light-emitting layer 21 covers at least the square opening 311 and is arranged in contact with the first carrier layer 27 and the second carrier layer 28. For example, when the first opening 312, the second opening 313, the third opening 314, and the fourth opening 315 are not filled by the electrode and the carrier layer, the light-emitting layer 21 also covers the regions of the first opening 312, the second opening 313, the third opening 314, and the fourth opening 315 that are not filled by the electrode and the carrier layer, so that the light-emitting layer 21 is in contact with the first carrier layer 27 and the second carrier layer 28.

It should be noted that, as shown in FIG. 3B, the first opening 312, the second opening 313, the third opening 314, and the fourth opening 315 may be of the sizes for only accommodating the corresponding electrodes to separate the electrodes, so that the carrier layer may be made in the square opening 311, and the carrier layers adjacent to each other may be in contact with each other or spaced apart from each other.

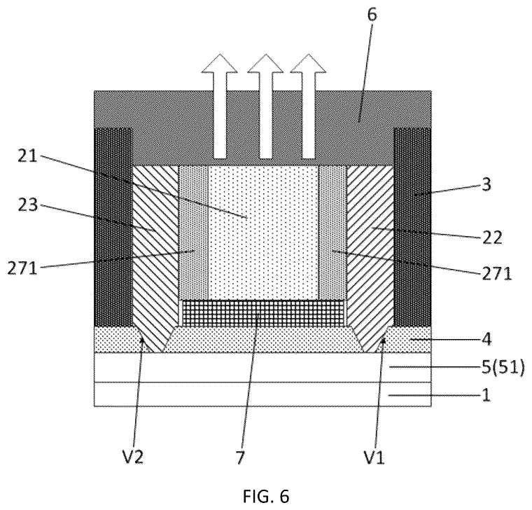

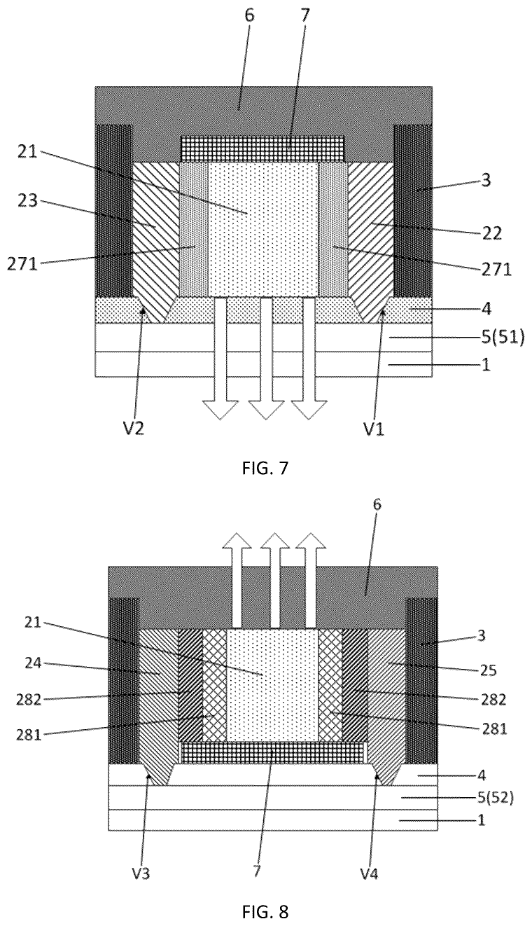

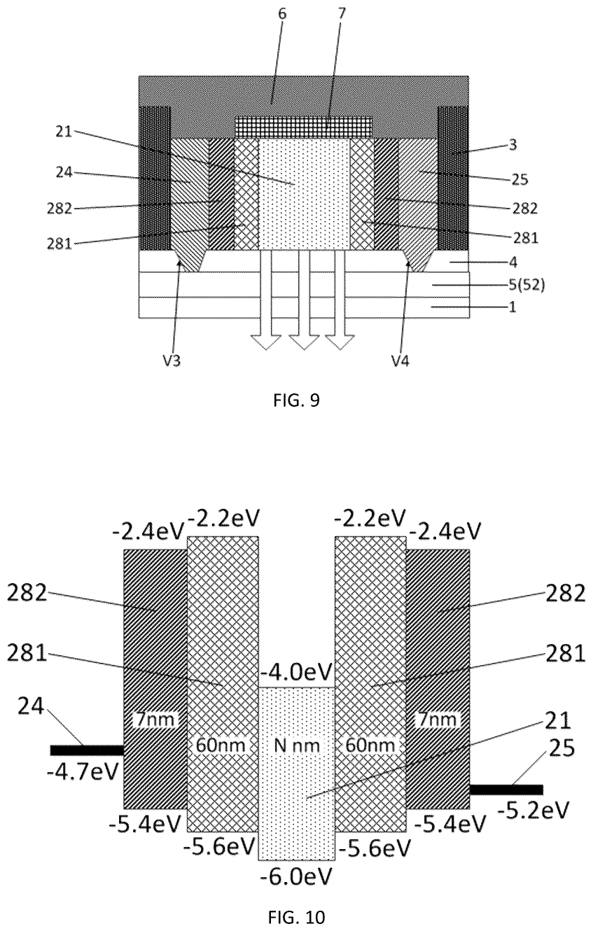

During specific implementation, in the light-emitting substrate provided by the embodiments of the present disclosure, as shown in FIG. 6 to FIG. 9, FIG. 6 and FIG. 7 are respectively two cross-sectional views along the direction CC′ in FIG. 2 and FIG. 3A, and FIG. 8 and FIG. 9 are respectively two cross-sectional views taken along the direction DD′ in FIG. 2 and FIG. 3A. The light-emitting substrate further includes: a planarization layer 4 located on a side of the base substrate 1 facing the light-emitting layer 21, a driving circuit layer 5 located between the planarization layer 4 and the base substrate 1, and an encapsulation layer 6 located on a side of the light-emitting layer 21 facing away from the base substrate 1.

The driving circuit layer 5 includes: a first driving circuit 51 corresponding one-to-one with the first electrode group (22 and 23), and a second driving circuit 52 corresponding one-to-one with the second electrode group (24 and 25). The first electrode 22 is electrically connected to the first driving circuit 51 through the first via hole V1 penetrating through the planarization layer 4, the second electrode 23 is electrically connected to the first driving circuit 51 through the second via hole V2 penetrating through the planarization layer 4, the third electrode 24 is electrically connected to the second driving circuit 52 through the third via hole V3 penetrating through the planarization layer 4, and the fourth electrode 25 is electrically connected to the second driving circuit 52 through the fourth via hole V4 penetrating through the planarization layer 4. In this way, the first driving circuit 51 loads the corresponding driving voltages to the first electrode 22 and the second electrode 23, and the second driving circuit 52 loads the corresponding driving voltages to the third electrode 24 and the fourth electrode 25, thereby achieving accurate control of the injection of electrons and holes.

It should be noted that the structure of each driving circuit mentioned above is the same as the structure of the driving circuit in the related art, and the difference between the present disclosure and the prior art lies in that each driving circuit refers to the first driving circuit for controlling the first electrode group and the second driving circuit for controlling the second electrode group.

In the present disclosure, the light-emitting type of the light-emitting device is not limited, for example, is not limited to bottom-emitting light or top-emitting light.

Optionally, in the light-emitting substrate provided by the embodiments of the present disclosure, as shown in FIG. 6 and FIG. 8, the light-emitting substrate further includes a metal reflective layer 7 located between the planarization layer 4 and the light-emitting layer 21, and an orthographic projection of the metal reflective layer 7 on the base substrate 1 does not overlap with an orthographic projection of the first electrode group (22 and 23) and the second electrode group (24 and 25) on the base substrate 1. In this way, the light-emitting device of top-emitting light may be formed, and the material of the metal reflective layer 7 may be any metal material or alloy material having a reflective effect.

Optionally, in the light-emitting substrate provided by the embodiments of the present disclosure, as shown in FIG. 7 and FIG. 9, the light-emitting substrate further includes a metal reflective layer 7 located between the encapsulation layer 6 and the light-emitting layer 21, and an orthographic projection of the metal reflective layer 7 on the base substrate 1 does not overlap with an orthographic projection of the first electrode group (22 and 23) and the second electrode group (24 and 25) on the base substrate 1. In this way, the light-emitting device of bottom-emitting light may be formed, and the material of the metal reflective layer 7 may be any metal material or alloy material having a reflective effect.

In specific implementation, in the above light-emitting substrate provided by the embodiments of the present disclosure, as shown in FIG. 2, FIG. 3A, and FIG. 6 to FIG. 9, a corner of a top view contour of the pixel definition layer 3 and an included angle between an inner wall of the pixel definition layer 3 and a surface of the base substrate 1 in the cross-sectional view are represented by right angles (mainly for clarity and convenience of drawing). Certainly, in an actual device or a product, a corner of the contour of the pixel definition layer 3 at the periphery of each light-emitting device 21 and an included angle between the inner wall of the pixel definition layer 3 and the surface of the base substrate 1 may be right angles or near right angles, or may exist at any reasonable angle chamfer, and the size and shape of the chamfer are jointly determined by the process conditions and the corresponding materials when preparing the pixel definition layer 3, which may be any reasonable angle value and shape. The specific angles and shapes of the present disclosure are not described again in the present disclosure.

During specific implementation, in the light-emitting substrate provided by the embodiments of the present disclosure, for materials of the first electrode 22, the second electrode 23, the third electrode 24, and the fourth electrode 25, various electrode materials in the related art (for example, including but not limited to metal, conductive metal oxide, conductive organic or conductive polymer materials, etc.), or a mixed electrode layer of a plurality of electrode materials, and a laminated composite electrode layer of a plurality of electrode materials. Optionally, each electrode may include at least one metal electrode capable of reflecting visible light to form effective reflection of light, thereby improving the light-emitting efficiency of the device.

Since the thickness of the light-emitting layer in the light-emitting device shown in FIG. 1 is generally only a few tens of nanometers in the light-emitting device shown in FIG. 1, the inventors of the present disclosure use the software Setfos to simulate and verify whether the thicker light-emitting layer 21 between the two electrodes in the present disclosure can meet the turned-on condition of the QLED device.

In the present disclosure, the HOD and the EOD of the laminated layers are separately simulated, and the thickness value of the light-emitting layer in the orthogonal light-emitting device provided by the present disclosure is assisted and inferred, and the light-emitting layer is a quantum dot light-emitting layer (QD) as an example.

The structure of the HOD is: a third electrode (e.g., ITO)/hole injection layer/hole transport layer/light-emitting layer/hole transport layer/hole injection layer/fourth electrode (e.g., Au). Thicknesses of these film layers along a direction pointing from the third electrode 24 to the fourth electrode 25 and energy level values of these film layers are shown in FIG. 10. Optionally, the third electrode 24 may be electrically connected to the positive electrode of the power supply, and the fourth electrode 25 may be connected to the negative electrode of the power supply. Of course, it may also be that the third electrode 24 is electrically connected to the negative electrode of the power supply, and the fourth electrode 25 is connected to the positive electrode of the power supply.

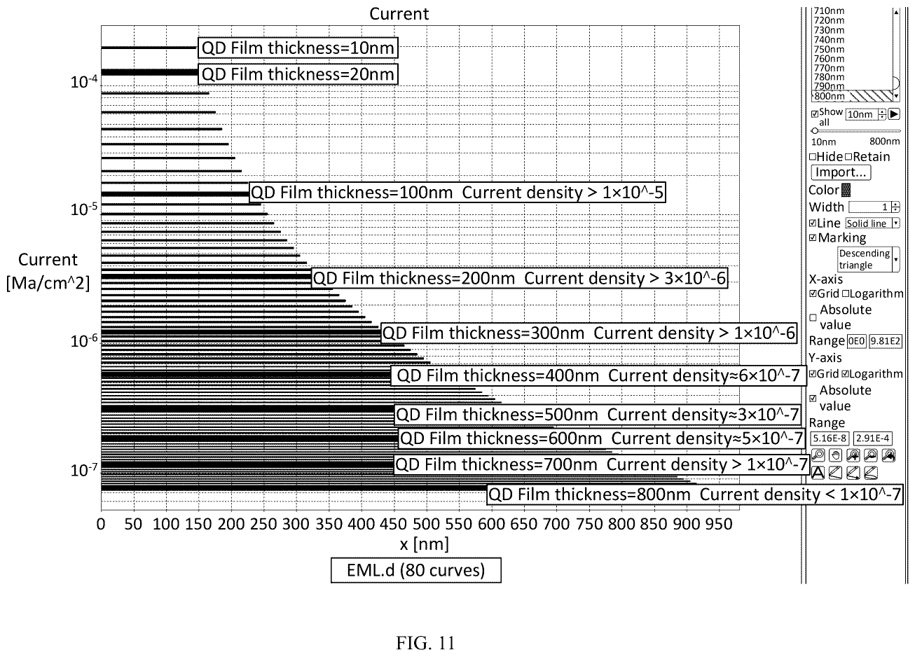

Simulation 1: The HOD of laminated layers is simulated at a constant voltage (e.g., voltage=6V), the thickness of QD is changed, and the change of the current density (J, unit: mA/cm²) in the HOD is simulated. The simulated QD has a thickness range N which is 10 nm to 800 nm, step=10 nm (i.e., simulated once every 10 nm), and the change of the current density J of the corresponding HOD under these thickness conditions is simulated. The result is shown in FIG. 11.

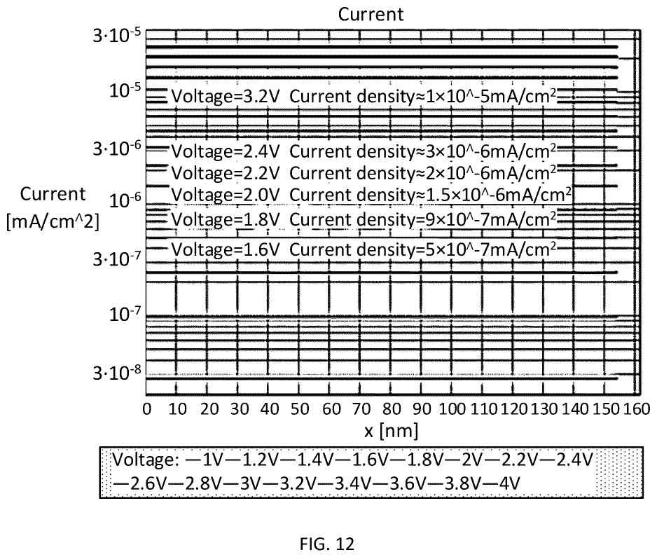

Simulation 2: The HOD of laminated layers is simulated at the fixed QD thickness (N=20 nm), the change of the current density (J, unit: mA/cm²) in the HOD is simulated under different voltages. The analog voltage ranges from 1V to 10V, step=0.2 V (i.e., simulated once every 0.2 V), and the change of the current density J of the corresponding HOD under these voltage conditions is simulated. The result is shown in FIG. 12 (only the result corresponding to 1 V-4 V is shown).

The change in the magnitude of the current density is as below by comparing the HOD, in simulation 1 and the HOD in the simulation 2.

Since the thickness of the quantum dot light-emitting layer in the QLED device in the related art ranges from 10 nm to 30 nm, the change of current density under the change voltage condition is simulated by taking the thickness of the quantum dot light-emitting layer as 20 nm (the result in simulation 2). Since the turned-on voltage of the common QLED device is displayed at 1.5 V-1.8 V, when the voltage=1.6 V, the current density corresponding to the HOD is J=5×10\hat{ }−7 mA/cm², so it can be inferred that the current density of the holes required for turning on the common QLED device is about 5×10\hat{ }−7 mA/cm². Considering that there is a certain difference between the hole injection and migration in the HOD and the hole injection and migration in the QLED device in the related art, when the QLED device is estimated to be capable of being turned on from the simulation result, the current density of the holes is at a level of the order of 10\hat{ }−7 mA/cm². At a constant voltage, the thickness of the quantum dot light-emitting layer is changed, the simulation result of the change of the current density of the HOD (the result in simulation 1) shows that, when the thickness N of the quantum dot light-emitting layer is less than or equal to 700 nm, the corresponding current density is greater than 1×10\hat{ }−7 mA/cm² (that is, when the QD film thickness N=700 nm, the current density J≈1.3×10\hat{ }−7 mA/cm²). Therefore, when the QD film thickness N is less than or equal to 700 nm, the hole concentration can meet the turned-on condition of the QLED device.

In addition, considering the difference between devices and the difference in energy levels of QDs, and the injection and transmission of carriers can be regulated by doping, it can be deduced that the orthogonal light-emitting device provided by the present disclosure can meet the QD film thickness N≤750 nm on which the light-emitting device is turned on.

Optionally, the thickness of the QD may be ≤600 nm, or ≤500 nm, or ≤400 nm, or ≤300 nm, or ≤200 nm.

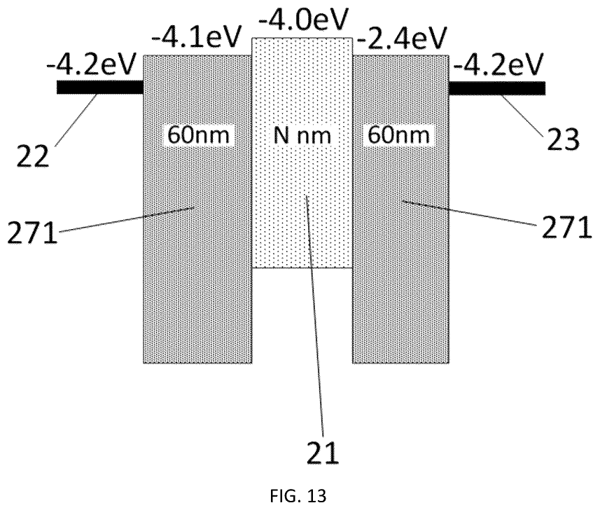

The structure of the EOD is: a first electrode (e.g., Ag)/electron transport layer/light-emitting layer/electron transport layer/second electrode (e.g., Ag). Thicknesses of these film layers along a direction pointing from the first electrode 22 to the second electrode 23 and the energy level values of these film layers are shown in FIG. 13. Optionally, the first electrode 22 may be electrically connected to the positive electrode of the power supply, and the second electrode 23 may be connected to the negative electrode of the power supply. Of course, it may also be that the first electrode 22 is electrically connected to the negative electrode of the power supply, and the second electrode 23 is connected to the positive electrode of the power supply.

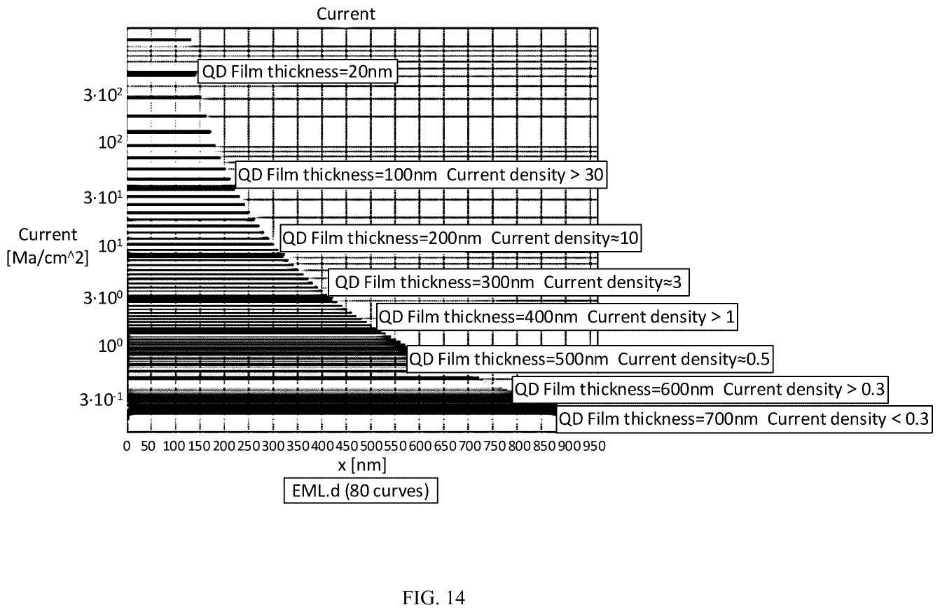

Simulation 3: The EOD of laminated layers is simulated at a constant voltage (e.g., voltage=6V), the thickness of the QD is changed, and the change of the current density (J, unit: mA/cm²) in the EOD is simulated. The simulated QD has a thickness range N which is 10 nm to 800 nm, step=10 nm (i.e., simulated once every 10 nm), and the change of the current density J of the corresponding EOD under these thickness conditions is simulated. The result is shown in FIG. 14.

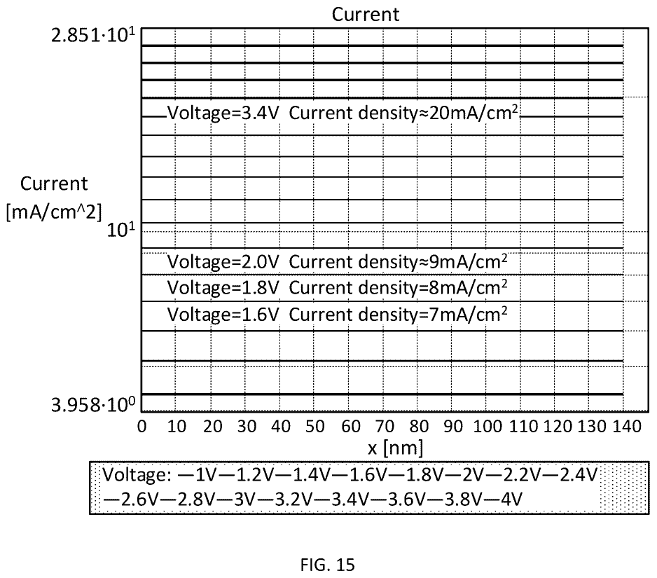

Simulation 4: The EOD of laminated layers is simulated at the fixed QD thickness (N=20 nm), the change of the current density (J, unit: mA/cm²) in the HOD is simulated under different voltages. The analog voltage ranges from 1V to 10V, step=0.2 V (i.e., simulated once every 0.2 V), and the change of the current density J of the corresponding EOD under these voltage conditions is simulated. The result is shown in FIG. 15 (only the result of 1-4 V is shown).

The change in the magnitude of the current density is as below by comparing the EOD in simulation 3 and the EOD in simulation 4.

By adopting the same analysis logic as the simulation result of the HOD, after comparison, from the perspective of the EOD, it can be estimated that the maximum thickness of the QD should be less than or equal to 750 nm. Optionally, the thickness of the QD may be ≤600 nm, or ≤500 nm, or ≤400 nm, or ≤300 nm, or ≤200 nm, or ≤100 nm.

During specific implementation, in the light-emitting substrate provided by the embodiments of the present disclosure, as shown in FIG. 2 and FIG. 3A, along the direction pointing from the first electrode 22 to the second electrode 23, the thickness H1 of the light-emitting layer 21 may range from 20 nm to 750 nm. Optionally, H1 may be 20 nm, 30 nm, 50 nm, 80 nm, 100 nm, 110 nm, 120 nm, 130 nm, 140 nm, 150 nm, 160 nm, 170 nm, 180 nm, 190 nm, 200 nm, 250 nm, 300 nm, 350 nm, 400 nm, 450 nm, 500 nm, 550 nm, 600 nm, 700 nm, or 750 nm.

Along the direction pointing from the third electrode 24 to the fourth electrode 25, the thickness H2 of the light-emitting layer 21 may range from 20 nm to 750 nm. Optionally, H2 may be 20 nm, 30 nm, 50 nm, 80 nm, 100 nm, 110 nm, 120 nm, 130 nm, 140 nm, 150 nm, 160 nm, 170 nm, 180 nm, 190 nm, 200 nm, 250 nm, 300 nm, 350 nm, 400 nm, 450 nm, 500 nm, 550 nm, 600 nm, 700 nm, or 750 nm.

Optionally, H1 and H2 may be the same or different.

During specific implementation, in the light-emitting substrate provided by the embodiments of the present disclosure, as shown in FIG. 2 and FIG. 3A, along the direction pointing from the first electrode 22 to the second electrode 23, the thickness H3 of the electron transport (ET) layer 271 may range from 20 nm to 250 nm, and the thickness of the ET layer is in a range of 20 nm≤T-ET≤250 nm. Preferably, T-ET may be 20 nm, 25 nm, 30 nm, 35 nm, 40 nm, 45 nm, 50 nm, 55 nm, 60 nm, 65 nm, 70 nm, 75 nm, 80 nm, 90 nm, 100 nm, 120 nm, 150 nm, 180 nm, or 200 nm. When the electron injection layer between the electron transport layer 27 and the first electrode 22 and/or the second electrode 23 is further included, the thickness of the electron injection layer may be 20 nm to 250 nm.

Along the direction pointing from the third electrode 24 to the fourth electrode 25, the thickness H4 of the hole injection layer 282 may range from 5 nm to 150 nm, and the thickness of the HI layer is in a range of 5 nm≤T-HI≤150 nm. Preferably, T-HI may be about 5 nm, 7 nm, 9 nm, 10 nm, 15 nm, 18 nm, 20 nm, 25 nm, 30 nm, 35 nm, 40 nm, 45 nm, 50 nm, 60 nm, 70 nm, 80 nm, or 100 nm. The thickness H5 of the hole transport layer 281 may range from 5 nm to 200 nm, and the thickness of the HT layer is in a range of 5 nm≤T-HT≤200 nm. Preferably, the T-HT may be 10 nm, 20 nm, 30 nm, 40 nm, 50 nm, 60 nm, 70 nm, 80 nm, 100 nm, 150 nm, or 200 nm.

During specific implementation, in the light-emitting substrate provided by the embodiments of the present disclosure, as shown in FIG. 2 and FIG. 3A, along the direction pointing from the first electrode 22 to the second electrode 23, the thickness H6 of the first electrode 22 may range from 50 nm to 400 nm. Optionally, H6 may be 80 nm, 100 nm, 120 nm, 150 nm, 200 nm, 300 nm, or 400 nm. The thickness of the second electrode 23 may be the same as the thickness H6 of the first electrode 22, where due to the process error, there may be a difference between the thickness of the second electrode 23 and the thickness H6 of the first electrode 22, which are not necessarily equal to each other.

During specific implementation, in the light-emitting substrate provided by the embodiments of the present disclosure, as shown in FIG. 2 and FIG. 3A, along the direction pointing from the third electrode 24 to the fourth electrode 25, the thickness H7 of the third electrode 24 may range from 50 nm to 400 nm. Optionally, H7 may be 80 nm, 100 nm, 120 nm, 150 nm, 200 nm, 300 nm, or 400 nm. The thickness of the fourth electrode 25 may be the same as the thickness H7 of the third electrode 24, where the thickness of the fourth electrode 25 may be different from the thickness H7 of the third electrode 24 due to the process error, which are not necessarily equal to each other.

In specific implementation, in the light-emitting substrate provided by the embodiments of the present disclosure, as shown in FIG. 6 to FIG. 9, along the direction perpendicular to a plane where the base substrate 1 is located, the height of the pixel defining layer 3 may range from 150 nm to 2000 nm, and the height of the light-emitting layer 21 may range from 10 nm to 500 nm.

The height of the first electrode group (22 and 23) and the height of the second electrode group (24 and 25) (the height in the non-via-hole region) each may be greater than or equal to 100 nm and less than or equal to a sum of the height of the pixel defining layer 3 and 40 nm. When the electrode material is actually deposited, the electrode material is deposited above the pixel defining layer 3, the target pattern is subsequently exposed through the photoresist, and then etched to leave the electrode at the target position. However, during actual exposure, the alignment precision is related, and there is no way to completely ensure that the pattern exposed by the photoresist is exactly the same as the edge of the pixel defining layer 3. In this case, the integrity of the electrode and the pixel defining layer 3 may be ensured by reducing the amount of over-etching of the etching process of the electrode, which may cause the electrode to be slightly higher than the pixel defining layer 3. Considering that the electrode layer 3 is too high to cause the electrode to be easily broken in the subsequent process, the height of the electrode is limited to be within 40 nm beyond the height of the pixel defining layer 3. Optionally, the height of the first electrode group (22 and 23) is less than the height of the pixel defining layer 3, and the height of the second electrode group (24 and 25) is less than the height of the pixel defining layer 3.

Based on the same reasons described above, the height of the first carrier layer 27 and the height of the second carrier layer 28 each may be greater than or equal to 50 nm and less than or equal to a sum of a first height and 20 nm, and the first height is the smaller height of the height of the first electrode group (22 and 23) and the height of the second electrode group (24 and 25), that is, the height of the carrier layer is limited to be within 20 nm beyond the height of the pixel defining layer 3.

In summary, compared with the light-emitting device of the laminated structure in the related art, the above-mentioned orthogonal light-emitting device provided by the embodiments of the present disclosure has the following beneficial effects.
1. By ingeniously leveraging the structure advantage of the above-mentioned orthogonal light-emitting device provided by the embodiments of the present disclosure, it is easy to apply different bias voltages to two ends of the first electrode and the second electrode respectively and two ends of the third electrode and the fourth electrode, respectively, so as to adjust the concentration of the injected holes and the concentration of the injected electrons in the device respectively through adjustment of the external voltage, thereby truly realizing injection balance of carriers in the device. That is, through the innovation of the structure in the present disclosure, different values of bias voltages are applied to affect and regulate the injection balance of the carriers in the device, so that the performance of the device is best.
2. In the above-mentioned orthogonal light-emitting device provided by the embodiments of the present disclosure, other film layers except the light-emitting layer may be prepared and produced based on the existing mature semiconductor process flow. The preparation of the light-emitting layer (e.g., QD light-emitting layer) can take into account various film processes, including direct photolithography patterning film-forming, indirect photolithography patterning film-forming, inkjet printing film-forming, doctor blade coating film-forming, slit coating film-forming, evaporation film-forming, spin coating film-forming, or the like.

3. Since the functional layers such as the electrode, the hole injection layer, the hole transport layer, the electron transport layer, and the like are all parallel to the light emission direction of the light-emitting layer, the microcavity effect inside the device can be basically eliminated, and the optical control and electrical regulation of the device are peeled off. Optical regulation of the device mainly focuses on a plane perpendicular to the light exit plane. In this device structure, the optical regulation of the part will not be affected by the electrical structure, and a larger degree of freedom optical structure design can be achieved.

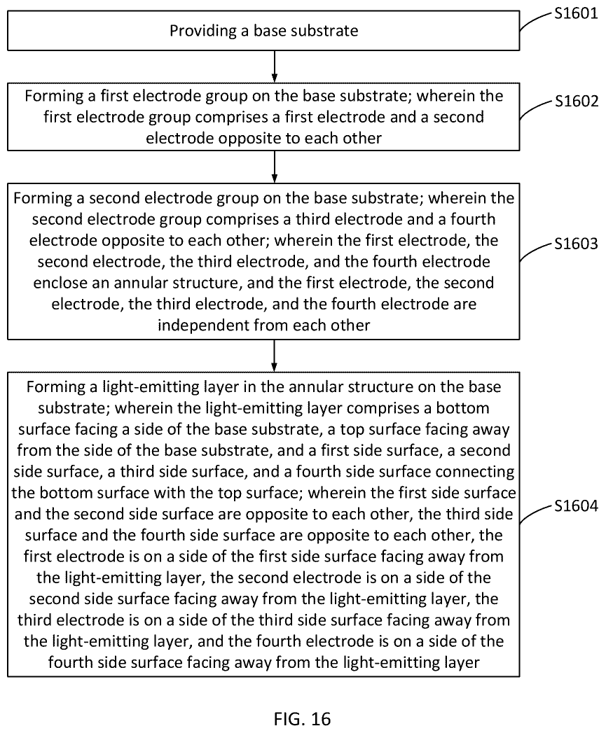

Based on the same inventive concept, an embodiment of the present disclosure further provides a manufacturing method for a light-emitting substrate, as shown in FIG. 16, including the following steps.

S1601, a base substrate is provided.

S1602, a first electrode group is formed on a base substrate, where the first electrode group includes a first electrode and a second electrode opposite to each other.

S1603, a second electrode group is formed on the base substrate; where the second electrode group includes a third electrode and a fourth electrode opposite to each other; where the first electrode, the second electrode, the third electrode, and the fourth electrode enclose an annular structure, and the first electrode, the second electrode, the third electrode, and the fourth electrode are independent from each other.

S1604, a light-emitting layer is formed in the annular structure and on the base substrate. The light-emitting layer includes a bottom surface facing a side of the base substrate, a top surface facing away from the side of the base substrate, and a first side surface, a second side surface, a third side surface, and a fourth side surface connecting the bottom surface with the top surface; where the first side surface and the second side surface are opposite to each other, the third side surface and the fourth side surface are opposite to each other, the first electrode is on a side of the first side surface facing away from the light-emitting layer, the second electrode is on a side of the second side surface facing away from the light-emitting layer, the third electrode is on a side of the third side surface facing away from the light-emitting layer, and the fourth electrode is on a side of the fourth side surface facing away from the light-emitting layer.

According to the manufacturing method for the light-emitting substrate provided by the embodiments of the present disclosure, the functional layers of the light-emitting device is manufactured on the same plane, that is, the shape of the light-emitting device may be similar to that of the vertical orthogonal-type device structure, and the holes and electrons in the light-emitting device can be regulated separately by applying bias voltages of different values on the two groups of electrodes, so that the true injection balance of holes and electrons can be more easily achieved.

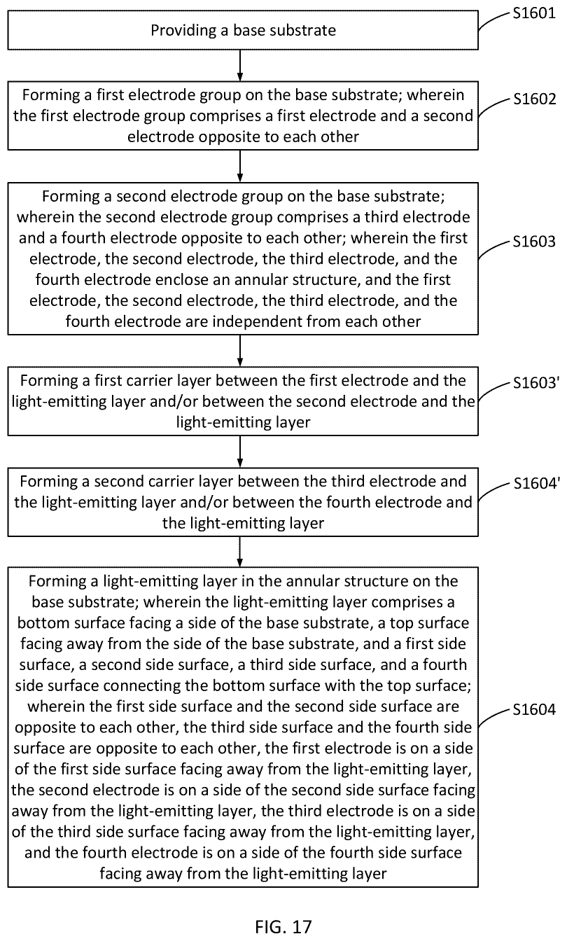

During specific implementation, in order to balance the concentration of electrons and the concentration of holes, in the above manufacturing method provided by the embodiments of the present disclosure, before forming the light-emitting layer, as shown in FIG. 17, the method further includes the following.

S1603′, a first carrier layer is formed between the first electrode and the light-emitting layer and/or between the second electrode and the light-emitting layer.

S1604′, a second carrier layer is formed between the third electrode and the light-emitting layer and/or between the fourth electrode and the light-emitting layer.

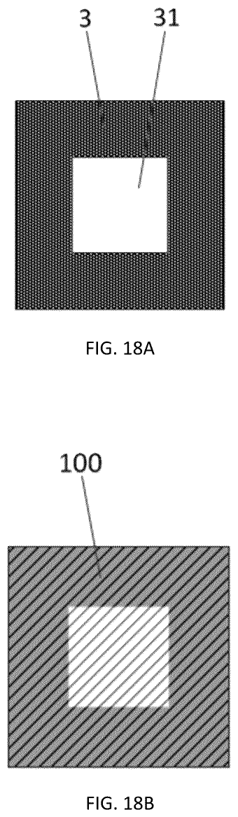

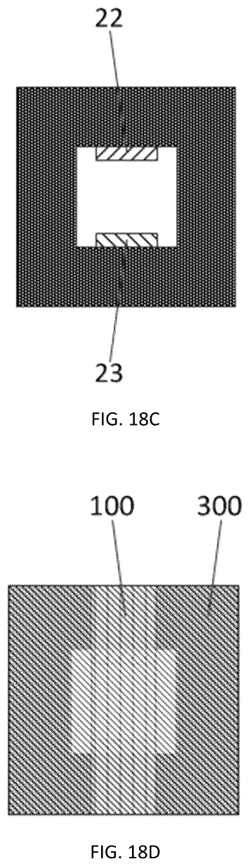

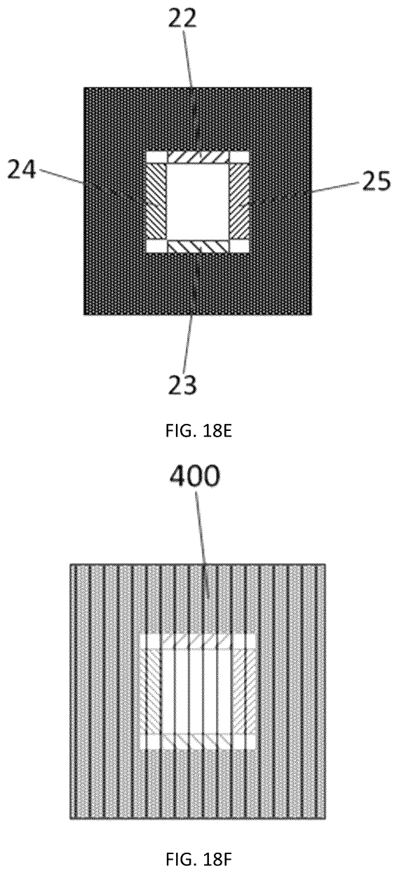

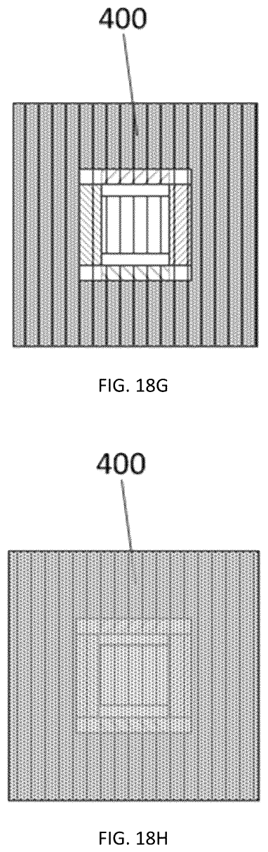

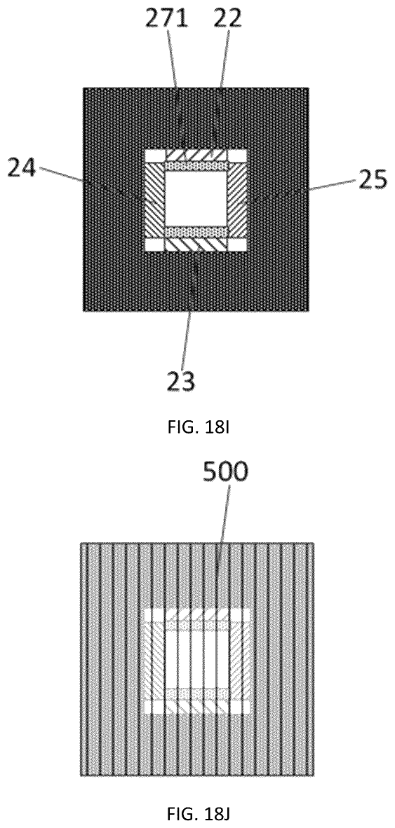

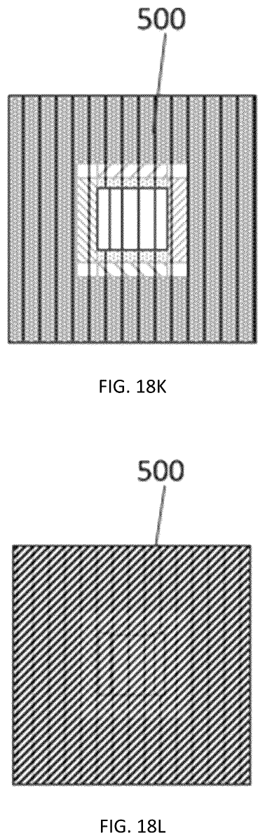

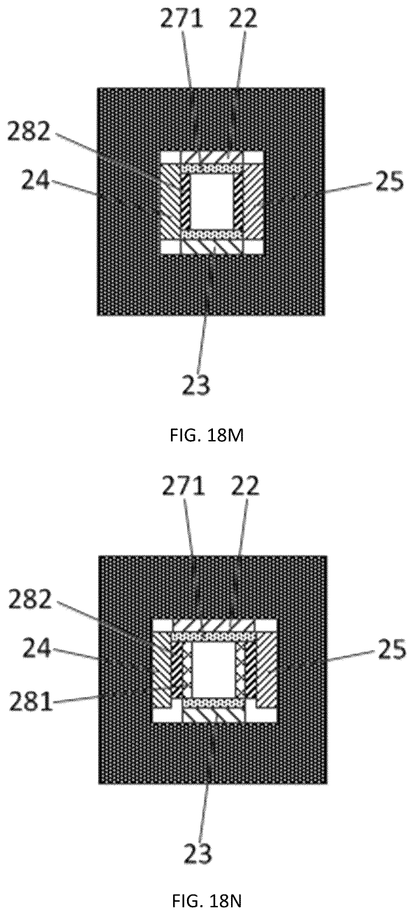

Taking the light-emitting substrate shown in FIG. 2 as an example, the manufacturing method for the light-emitting substrate provided by the embodiments of the present disclosure will be described, which includes the following steps.
(1) A pixel defining layer 3 is formed on the base substrate (not shown), and the pixel defining layer 3 has a pixel opening 31, as shown in FIG. 18A.
(2) A first electrode film layer 100 for fabricating the first electrode and the second electrode is deposited on the entire surface of the pixel defining layer 3, and a first photoresist layer (not shown) is coated on the first electrode film layer 100, as shown in FIG. 18B. The first electrode 22 and the second electrode 23 are prepared in the pixel opening 31 by exposing and developing the first photoresist layer and etching the first electrode film layer 100, as shown in FIG. 18C.
(3) A second photoresist layer 200 is coated on the first electrode 22 and the second electrode 23, a second electrode film layer 300 for fabricating the third electrode and the fourth electrode is deposited on the entire surface of the second photoresist layer 200, and a third photoresist layer (not shown) is coated on the second electrode film layer 300, as shown in FIG. 18D. By exposing and developing the third photoresist layer and simultaneously developing the second photoresist layer 200, and by etching the second electrode film layer 300, the third electrode 24 and the fourth electrode 25 are prepared in the pixel opening 31, as shown in FIG. 18E.
(4) A fourth photoresist layer 400 is coated on the base substrate prepared with the first electrode 22, the second electrode 23, the third electrode 24, and the fourth electrode 25, as shown in FIG. 18F. The position of the electron transport layer 271 is exposed through exposure and development processes, as shown in FIG. 18G. Then, the entire electron transport material is deposited, as shown in FIG. 18H. Then, by peeling off the fourth photoresist layer 400, the excess electron transport material is peeled together with the fourth photoresist layer 400 to realize the deposition of the electron transport layer 271 at a specific position, as shown in FIG. 18I.
(5) A fifth photoresist layer 500 is coated on the base substrate prepared with the first electrode 22, the second electrode 23, the third electrode 24, the fourth electrode 25 and the electron transport layer 271, as shown in FIG. 18J. The position of the hole injection layer 282 is exposed through exposure and development processes, as shown in FIG. 18K. Then, the entire hole injection material is deposited, as shown in FIG. 18L. Then, by peeling off the fifth photoresist layer 500, the excess hole injection material is peeled together with the fifth photoresist layer 500 to realize the deposition of the hole injection layer 282 at a specific position, as shown in FIG. 18M. Then, the hole transport layer 281 is formed on the side of the hole injection layer 282 facing away from the third electrode 24 and the side of the hole injection layer 282 facing away from the fourth electrode 25 by using the same process for manufacturing the hole injection layer 282, as shown in FIG. 18N.
(6) The light-emitting layer 21 is formed in the annular structure enclosed by the two electron transport layers 271 and the two hole transport layers 281 on the basis of FIG. 18N. The material of the light-emitting layer 21 may be quantum dots, perovskite, organic light-emitting materials, and the like. The manufacturing process of the light-emitting layer 21 of the quantum dot material includes a direct photolithography patterning film-forming, an indirect photolithography patterning film-forming, an inkjet printing film-forming (including electrospray printing), a doctor blade coating film-forming, a slit coating film-forming, a spin coating film-forming, a printing film-forming, a spraying film-forming, a transfer printing film-forming, and the like. For the organic light-emitting material or/and the perovskite light-emitting material, film deposition can also be performed by means of evaporation to complete the deposition of a light-emitting layer of a wavelength, as shown in FIG. 18O. Then, the manufacturing for the two light-emitting layers is repeated, so that the light-emitting layers with different light-emitting wavelengths can be prepared, that is, the preparation of the full-color device can be realized.
(7) The light-emitting device shown in FIG. 18O is encapsulated, that is, a complete QLED or OLED device may be formed.

It should be noted that, as shown in FIG. 2, in the included angle space between the first electrode group and the second electrode group (the blank region formed between the light-emitting device 2 and the pixel definition layer 3 in FIG. 2), the blank region is filled by the encapsulation layer. Meanwhile, since materials such as the hole injection layer, the hole transport layer, the electron transport layer, and the light-emitting layer are all deposited before the encapsulation layer, and the depositions of these layers have a certain alignment error, there will also be one or more thin films of one or more materials of the hole injection layer, the hole transport layer, the electron transport layer, and the light-emitting layer in the blank region, and the thin films of these materials are all below the encapsulation layer.

It should be noted that the light-emitting device shown in FIG. 2 is more suitable for the high exposure precision of the photolithography machine, and the matching etching accuracy is also high, so that the two electrode groups are not in contact with each other without the aid of the structure of the pixel defining layer 3, that is, the first electrode 22 is not in contact with the third electrode 24 and the fourth electrode 25 in space, and the second electrode 23 is not in contact with the third electrode 24 and the fourth electrode 25 in space.

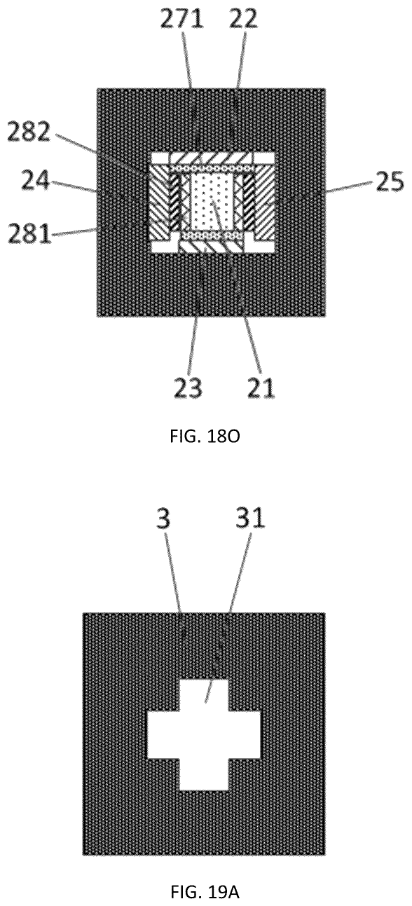

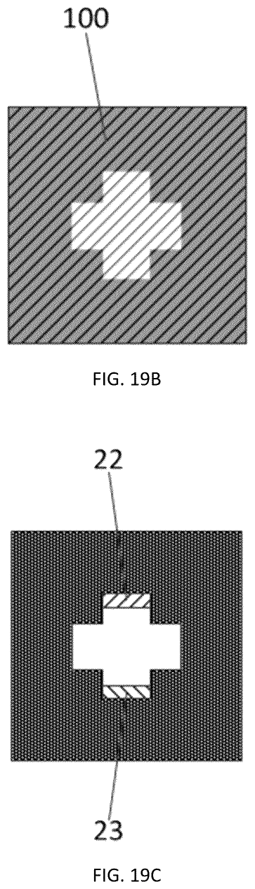

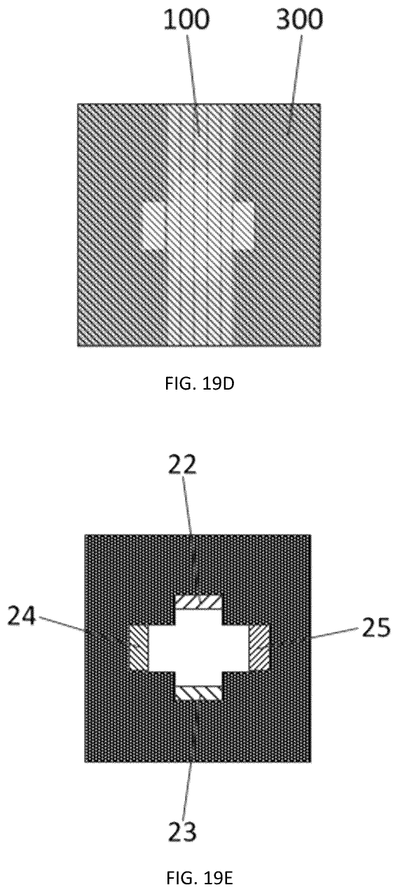

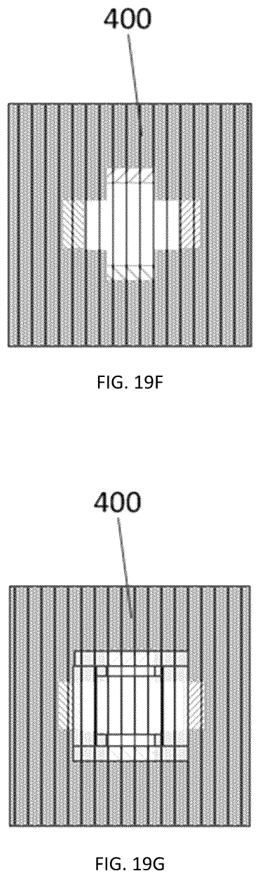

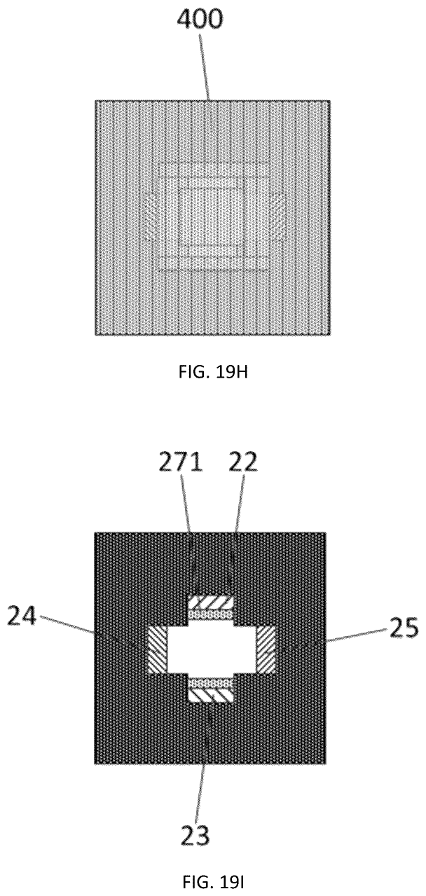

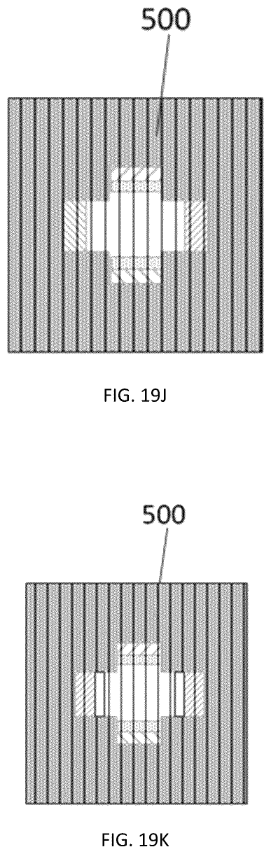

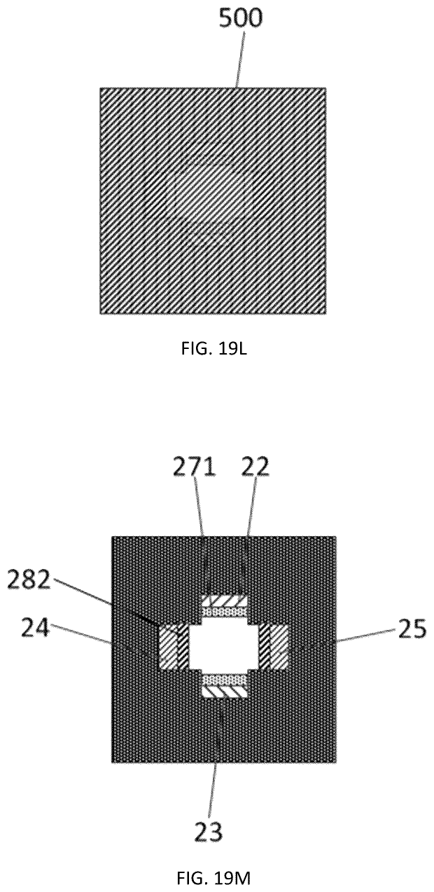

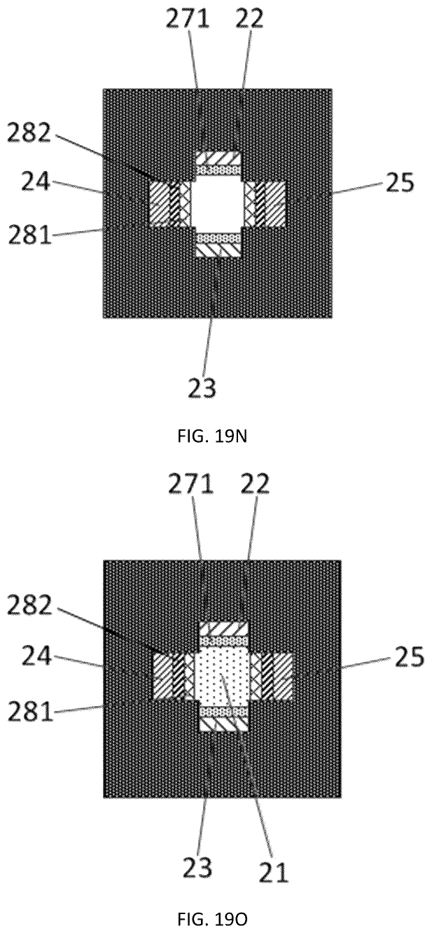

The manufacturing process flow of the light-emitting device shown in FIG. 3A is basically the same as the manufacturing process flow of the light-emitting device shown in FIG. 2, and the main difference point between the two is that the shapes of the pixel openings 31 of the pixel defining layers 3 are different. When manufacturing the light-emitting device shown in FIG. 3A, it is necessary to design the pixel opening 31 of the pixel defining layer 3 to ensure that the first electrode group and the second electrode group are spatially separated from each other and not in contact with each other. FIG. 19A to FIG. 190 are schematic diagrams of process flow when manufacturing the light-emitting device shown in FIG. 3A.

Based on the same inventive concept, an embodiment of the present disclosure further provides a display device, including the above light-emitting substrate provided by the embodiments of the present disclosure. The principle of the display device to solve the problem is similar to that of the aforementioned light-emitting substrate, so the implementation of the display device can refer to the implementation of the aforementioned light-emitting substrate, and will not be repeated here.

In specific implementation, the display device provided by the embodiments of the present disclosure may be a full-screen display device, or may be a flexible display device, etc., which is not limited herein.

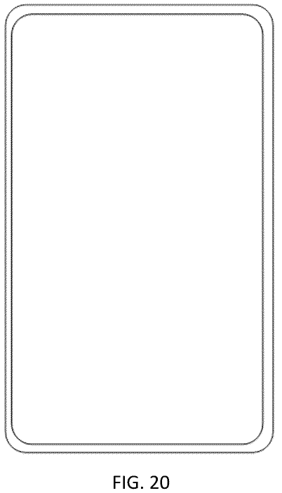

In specific implementation, the display device provided by the embodiments of the present disclosure may be a mobile phone with a full screen as shown in FIG. 20. Certainly, the display device provided by the embodiments of the present disclosure may also be any product or component having a display function, such as a tablet computer, a television, a display, a notebook computer, a digital photo frame, a navigator, and the like. Other essential components of the display device should be understood by those of ordinary skill in the art, and will not be repeated here, nor should they be used as a limitation to the present disclosure.

According to the light-emitting substrate and the manufacturing method therefor, and the display device provided by the embodiments of the present disclosure, the functional layers of the light-emitting device are disposed on the same plane, that is, the shape of the light-emitting device may be similar to that of the vertical orthogonal-type device structure, and the holes and electrons in the light-emitting device can be regulated separately by applying bias voltages of different values on the two groups of electrodes, so that the true injection balance of holes and electrons can be more easily achieved.

Obviously, those skilled in the art can make various modifications and variations to the present disclosure without departing from the spirit and scope of the present disclosure. Thus, if these modifications and variations of the present disclosure fall within the scope of the claims of the present disclosure and their equivalent technologies, the present disclosure is also intended to include these modifications and variations.

1. A light-emitting substrate, comprising a base substrate and a light-emitting device on the base substrate, wherein the light-emitting device comprises:
a light-emitting layer on the base substrate; wherein the light-emitting layer comprises a bottom surface facing a side of the base substrate, a top surface facing away from the side of the base substrate, and a first side surface, a second side surface, a third side surface, and a fourth side surface connecting the bottom surface with the top surface; wherein the first side surface and the second side surface are opposite to each other, and the third side surface and the fourth side surface are opposite to each other;
a first electrode group, comprising a first electrode and a second electrode; wherein the first electrode is on the base substrate and on a side of the first side surface facing away from the light-emitting layer, and the second electrode is on the base substrate and on a side of the second side surface facing away from the light-emitting layer; and
a second electrode group, comprising a third electrode and a fourth electrode; wherein the third electrode is on the base substrate and on a side of the third side surface facing away from the light-emitting layer, and the fourth electrode is on the base substrate and on a side of the fourth side surface facing away from the light-emitting layer; wherein the first electrode, the second electrode, the third electrode, and the fourth electrode are independent from each other.

2. The light-emitting substrate according to claim 1, wherein the light-emitting device further comprises:
a first carrier layer between at least one electrode in the first electrode group and the light-emitting layer; and
a second carrier layer between at least one electrode in the second electrode group and the light-emitting layer.

3. The light-emitting substrate according to claim 2, wherein the first carrier layer is disposed between the first electrode and the light-emitting layer and between the second electrode and the light-emitting layer; and
the second carrier layer is disposed between the third electrode and the light-emitting layer and between the fourth electrode and the light-emitting layer.

4. The light-emitting substrate according to claim 3, wherein:
the first carrier layer comprises at least one of an electron transport layer and an electron injection layer; and
the second carrier layer comprises at least one of a hole transport layer and a hole injection layer; wherein a first carrier injected into the first carrier layer is an electron, and a second carrier injected into the second carrier layer is a hole;
wherein based on that the first carrier layer comprises the electron transport layer and the electron injection layer, the electron transport layer is between the electron injection layer and the light-emitting layer; and based on that the second carrier layer comprises the hole transport layer and the hole injection layer, the hole transport layer is between the hole injection layer and the light-emitting layer.

5. The light-emitting substrate according to claim 2, further comprising:
a pixel defining layer on the base substrate; wherein the pixel defining layer is provided with a pixel opening, and the light-emitting device is in the pixel opening;
wherein a shape of an orthographic projection of the pixel opening on the base substrate is square.

6. The light-emitting substrate according to claim 5, wherein the first carrier layer and the second carrier layer are independent from each other, or the first carrier layer and the second carrier layer are in contact with each other.

7. The light-emitting substrate according to claim 2, further comprising:
a pixel defining layer on the base substrate; wherein the pixel defining layer is provided with a pixel opening, and the light-emitting device is in the pixel opening;
wherein the pixel opening comprises: a square opening, and a first opening, a second opening, a third opening, and a fourth opening respectively connected to side edges of the square opening and extending from sides of the square opening to outside; and a shape of an orthographic projection of the square opening on the base substrate is square; and
openings, that are adjacent to each other, of the first opening, the second opening, the third opening, and the fourth opening are spaced apart from each other, and the square opening communicates with the first opening, the second opening, the third opening, and the fourth opening.

8. The light-emitting substrate according to claim 7, wherein the first electrode is in the first opening, the second electrode is in the second opening, the third electrode is in the third opening, and the fourth electrode is in the fourth opening;
the first carrier layer is in the first opening and/or the second opening, and the second carrier layer is in the third opening and/or the fourth opening; and
the light-emitting layer at least covers the square opening and is in contact with the first carrier layer and the second carrier layer.

9. The light-emitting substrate according to claim 1, further comprising:
a planarization layer on a side of the base substrate facing the light-emitting layer, a driving circuit layer between the planarization layer and the base substrate, and an encapsulation layer on a side of the light-emitting layer facing away from the base substrate;
wherein the driving circuit layer comprises: a first driving circuit corresponding one-to-one with the first electrode group, and a second driving circuit corresponding one-to-one with the second electrode group;
wherein the first electrode is electrically connected to the first driving circuit through a first via hole penetrating through the planarization layer, the second electrode is electrically connected to the first driving circuit through a second via hole penetrating through the planarization layer, the third electrode is electrically connected to the second driving circuit through a third via hole penetrating through the planarization layer, and the fourth electrode is electrically connected to the second driving circuit through a fourth via hole penetrating through the planarization layer.

10. The light-emitting substrate according to claim 9, further comprising:
a metal reflective layer between the planarization layer and the light-emitting layer; wherein an orthographic projection of the metal reflective layer on the base substrate does not overlap with an orthographic projection of the first electrode group and the second electrode group on the base substrate.

11. The light-emitting substrate according to claim 9, further comprising:
a metal reflective layer between the encapsulation layer and the light-emitting layer; wherein an orthographic projection of the metal reflective layer on the base substrate does not overlap with an orthographic projection of the first electrode group and the second electrode group on the base substrate.

12. The light-emitting substrate according to claim 1, wherein along a direction pointing from the first electrode to the second electrode, a thickness of the light-emitting layer ranges from 20 nm to 750 nm; and
along a direction pointing from the third electrode to the fourth electrode, a thickness of the light-emitting layer ranges from 20 nm to 750 nm.

13. The light-emitting substrate according to claim 4, wherein along a direction pointing from the first electrode to the second electrode, a thickness of the electron injection layer ranges from 20 nm to 250 nm and a thickness of the electron transport layer ranges from 20 nm to 250 nm; and
along a direction pointing from the third electrode to the fourth electrode, a thickness of the hole injection layer ranges from 5 nm to 150 nm and a thickness of the hole transport layer ranges from 5 nm to 200 nm.

14. The light-emitting substrate according to claim 1, wherein along a direction pointing from the first electrode to the second electrode, a thickness of the first electrode ranges from 50 nm to 400 nm and a thickness of the second electrode ranges from 50 nm to 400 nm; and
along a direction pointing from the third electrode to the fourth electrode, a thickness of the third electrode ranges from 50 nm to 400 nm and a thickness of the fourth electrode ranges from 50 nm to 400 nm.

15. The light-emitting substrate according to claim 5, wherein along a direction perpendicular to a plane where the base substrate is located, a height of the pixel defining layer ranges from 150 nm to 2000 nm, and a height of the light-emitting layer is 10 nm-500 nm;
a height of the first electrode group is greater than or equal to 100 nm and less than or equal to a sum of a height of the pixel defining layer and 40 nm, and a height of the second electrode group is greater than or equal to 100 nm and less than or equal to the sum of the height of the pixel defining layer and 40 nm; and
a height of the first carrier layer is greater than or equal to 50 nm and less than or equal to a sum of a first height and 20 nm, and a height of the second carrier layer is greater than or equal to 50 nm and less than or equal to the sum of the first height and 20 nm; wherein the first height is a smaller height of the height of the first electrode group and the height of the second electrode group.

16. A display device, comprising the light-emitting substrate according to claim 1.

17. A manufacturing method for a light-emitting substrate, comprising:
providing a base substrate;
forming a first electrode group on the base substrate; wherein the first electrode group comprises a first electrode and a second electrode opposite to each other;
forming a second electrode group on the base substrate; wherein the second electrode group comprises a third electrode and a fourth electrode opposite to each other; wherein the first electrode, the second electrode, the third electrode, and the fourth electrode enclose an annular structure, and the first electrode, the second electrode, the third electrode, and the fourth electrode are independent from each other; and
forming a light-emitting layer in the annular structure on the base substrate; wherein the light-emitting layer comprises a bottom surface facing a side of the base substrate, a top surface facing away from the side of the base substrate, and a first side surface, a second side surface, a third side surface, and a fourth side surface connecting the bottom surface with the top surface; wherein the first side surface and the second side surface are opposite to each other, the third side surface and the fourth side surface are opposite to each other, the first electrode is on a side of the first side surface facing away from the light-emitting layer, the second electrode is on a side of the second side surface facing away from the light-emitting layer, the third electrode is on a side of the third side surface facing away from the light-emitting layer, and the fourth electrode is on a side of the fourth side surface facing away from the light-emitting layer.

18. The manufacturing method according to claim 17, wherein before forming the light-emitting layer, the method further comprises:
forming a first carrier layer between the first electrode and the light-emitting layer and/or between the second electrode and the light-emitting layer; and
forming a second carrier layer between the third electrode and the light-emitting layer and/or between the fourth electrode and the light-emitting layer.

19. The light-emitting substrate according to claim 4, wherein:
the first carrier layer comprises at least one of an electron transport layer and an electron injection layer; and
the second carrier layer comprises at least one of a hole transport layer and a hole injection layer; wherein a first carrier injected into the first carrier layer is an electron, and a second carrier injected into the second carrier layer is a hole;
wherein based on that the first carrier layer comprises the electron transport layer and the electron injection layer, the electron transport layer is between the electron injection layer and the light-emitting layer; and based on that the second carrier layer comprises the hole transport layer and the hole injection layer, the hole transport layer is between the hole injection layer and the light-emitting layer.

20. The light-emitting substrate according to claim 3, further comprising:
a pixel defining layer on the base substrate; wherein the pixel defining layer is provided with a pixel opening, and the light-emitting device is in the pixel opening;
wherein a shape of an orthographic projection of the pixel opening on the base substrate is square.
